(19) United States
(12) Patent Application Publication
(10) Pub. No.: US 2016/0255737 A1
(43) Pub. Date: Sep. 1, 2016

(54) ELECTRONIC DEVICE IN LIGHTWEIGHT HOUSING

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: YU-MING XIAO, Wuhan (CN); LIANG-CHIN WANG, New Taipei (TW); CHIANG-JEN CHUNG, New Taipei (TW); ZAN LI, Wuhan (CN); CHUAN LIN, Wuhan (CN)

(21) Appl. No.: 14/682,949

(22) Filed: Apr. 9, 2015

(30) Foreign Application Priority Data
Feb. 27, 2015 (CN) 201510089030.9

(51) Int. Cl. H05K 5/04; H05K 5/03; H05K 5/02; H05K 5/00

(52) U.S. Cl. CPC H05K 5/04; H05K 5/0004; H05K 5/03; H05K 5/0247; H05K 5/0217

(57) ABSTRACT

An electronic device includes a non-metallic main body, a front panel, a rear panel, and a circuit board received in the main body. The main body defines a first opening and a second opening relative to the first opening. The front panel is received in the first opening. The rear panel is received in the second opening and electrically coupled to a ground wire of the circuit board.

### CROSS-REFERENCE TO RELATED APPLICATIONS

This application claims priority to Chinese Patent Application No. 201510089030.9 filed on Fe. 27, 2015, the contents of which are hereby incorporated by reference.

### FIELD

The subject matter herein generally relates to casing materials.

### BACKGROUND

An electronic device generally includes a chassis made of metal and a plurality of components received in the chassis. Metal has a great density, which causes the chassis to be heavy.

### BRIEF DESCRIPTION OF THE DRAWINGS

Implementations of the present technology will now be described, by way of example only, with reference to the attached figures.

FIG. 1 is an exploded, isometric view of an electronic device in accordance with a first embodiment.

FIG. 2 is an isometric view of the partially assembled electronic device of FIG. 1.

FIG. 3 is an assembled, isometric view of the electronic device of FIG. 1.

FIG. 4 is an exploded, isometric view of an electronic device of FIG. 1 in accordance with a second embodiment.

FIG. 5 is an isometric view of a main body of the electronic device of FIG. 4.

FIG. 6 is an assembled, isometric of the electronic device of FIG. 4, wherein an inlet of a chassis of the electronic device is shown.

FIG. 7 is an assembled, isometric of the electronic device of FIG. 4, wherein the inlet of the chassis of the electronic device is closed.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

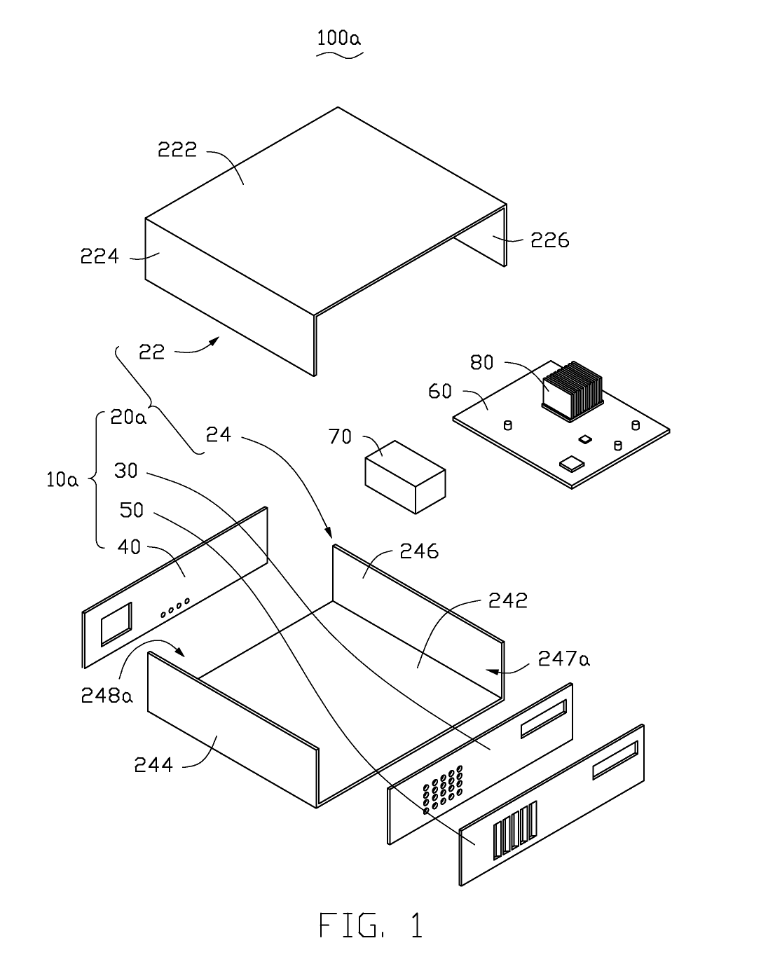

FIG. 1 illustrates a first embodiment of an electronic device 100a which can include a chassis 10a, a circuit board 60, a power supply 70, and a heat sink 80 mounted on the circuit board 60. The circuit board 60 has a plurality of electronic components.

The chassis 10a can include a non-metallic main body 20a, a front panel 30, a metallic rear panel 40, and a bezel 50. The main body 20a can include a U-shaped cover 22 and a U-shaped base 24. In at least one embodiment, the main body 20a is made of paper or plastic materials, the U-shaped cover 22 is a folded plate, and the U-shaped base 24 is another folded plate.

The cover 22 includes a covering plate 222, a first folded plate 224, and a second folded plate 226. The first folded plate 224 and the second folded plate 226 are substantially parallel to each other and perpendicularly connected to opposite sides of the covering plate 222.

The base 24 can include a bottom wall 242, a first sidewall 244, and a second sidewall 246. The first sidewall 244 and the second sidewall 246 are substantially parallel to each other and perpendicularly connected to opposite sides of the bottom wall 242. The base 24 defines a first opening 247a and a second opening 248a opposite to the first opening 247a. The first opening 247a and the second opening 248a are surrounded corporately by the bottom wall 242, the first sidewall 244, and the second sidewall 246.

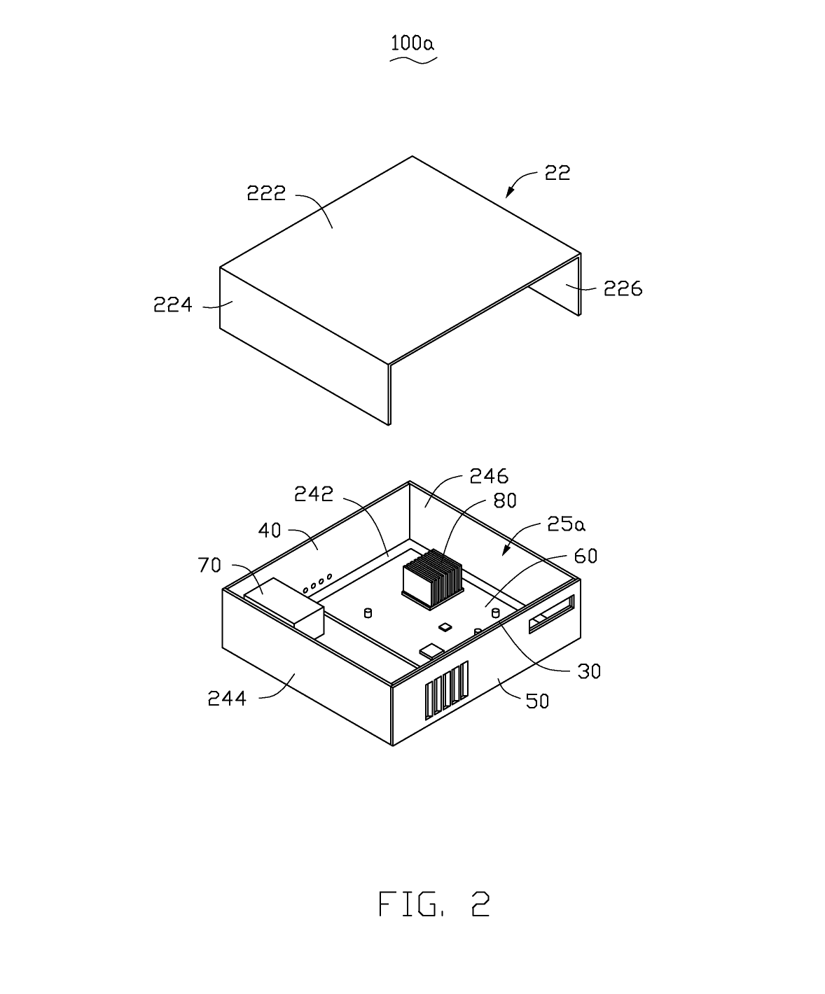

FIG. 2 illustrates assembly of the electronic device 100a, before the cover 22 is mounted to the base 24. The front panel 30 is received in the first opening 247a and abuts the bottom wall 242, the first sidewall 244, and the second sidewall 246. The rear panel 40 is received in the second opening 248a and abuts the bottom wall 242, the first sidewall 244, and the second sidewall 246. A first inlet 25a is defined corporately by the first sidewall 244, the second sidewall 246, the front panel 30, and the rear panel 40. The circuit board 60 is inserted through the first inlet 25a and secured on the bottom wall 242. The power supply 70 is attached to the rear panel 40 and electronically connected to the circuit board 60 by a cable (not shown). The rear panel 40 is electronically coupled to a ground wire of the circuit board 60. The bezel 50 is attached to the front panel 30.

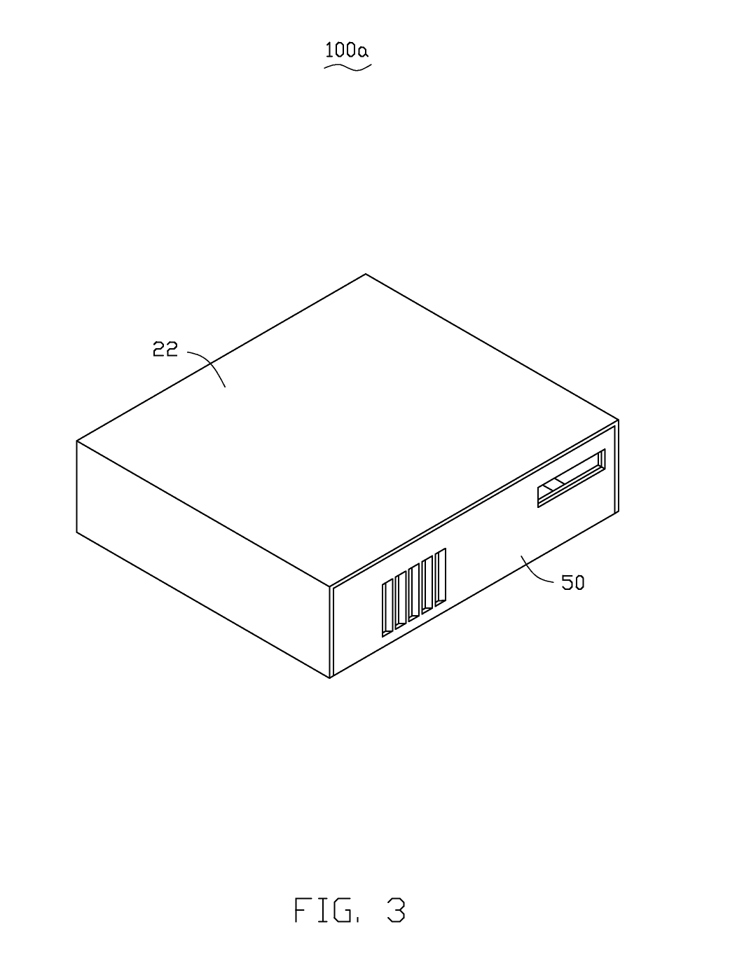

FIG. 3 illustrates the electronic device 100a in assembly. The cover 22 is mounted to the base 24. The first folded plate 224 is mounted on the first sidewall 244, the second folded plate 226 is mounted on the second sidewall 246, and the first inlet 25a is closed by the covering plate 222. In at least one embodiment, the cover 22 can be mounted to the base by locking, magnetic attraction, and other means.

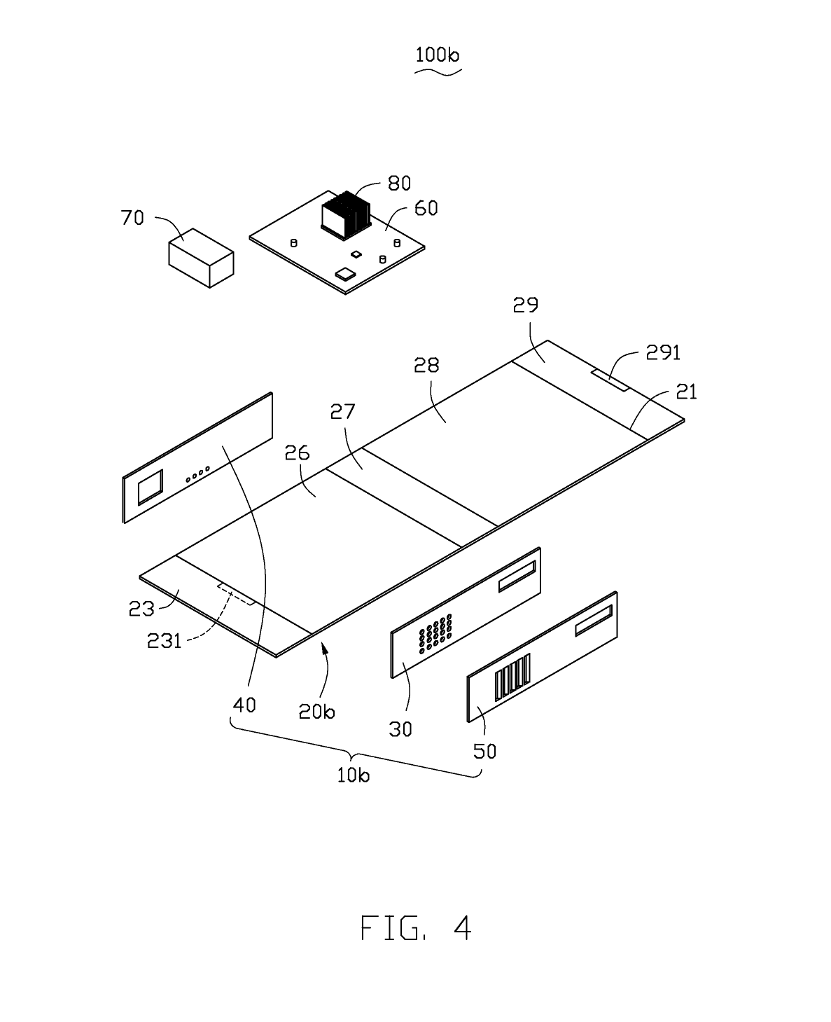

FIG. 4 illustrates a second embodiment of electronic device 100b which can include a chassis 10b, the circuit board 60, the power supply 70, and the heat sink 80 mounted on the circuit board 60.

The chassis 10b can include a main body 20b, the front panel 30, the rear panel 40, and the bezel 50. The main body 20b is a rectangular panel in a first status which can be folded. A plurality of parallel folding-lines 21 is impressed on the foldable panel, and the foldable panel is divided into a plurality of areas according to the plurality of folding-lines 21.

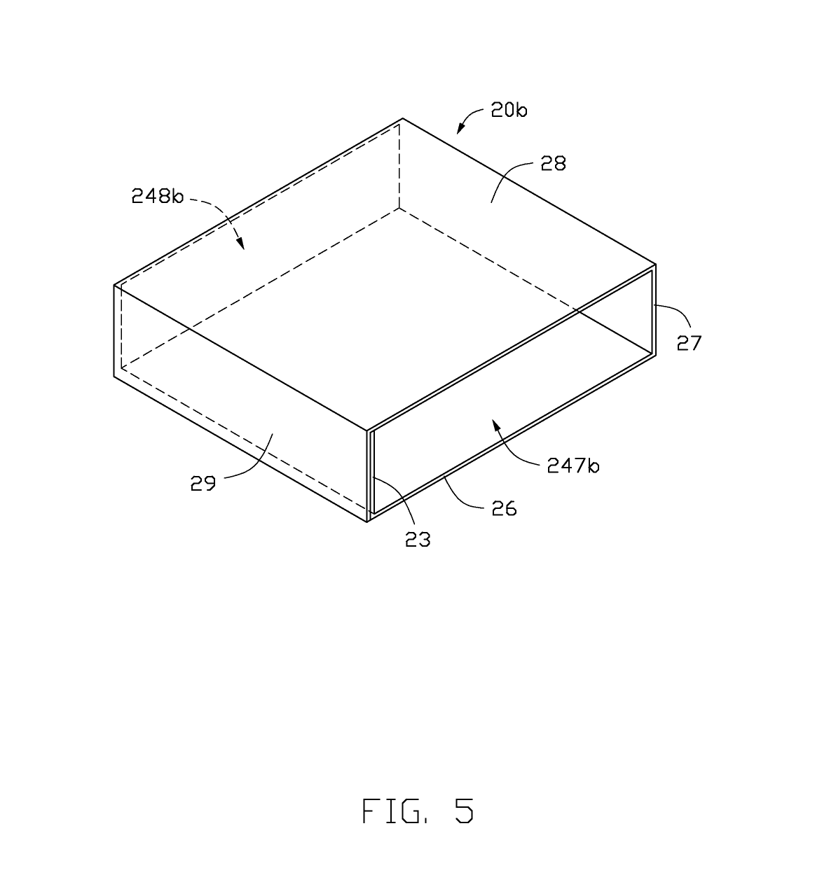

FIG. 5 illustrates the main body 20b in a second status. The foldable panel is folded along the plurality of folding-lines to define an enclosed configuration and forms a first side panel 23, a bottom panel 26, a second side panel 27, a covering panel 28, and a third side panel 29. The main body 20b defines a first opening 247b and a second opening 248b opposite to the first opening 247b. The first opening 247b and the second opening 248b are surrounded by the first side panel 23, the bottom panel 26, and the second side panel 27.

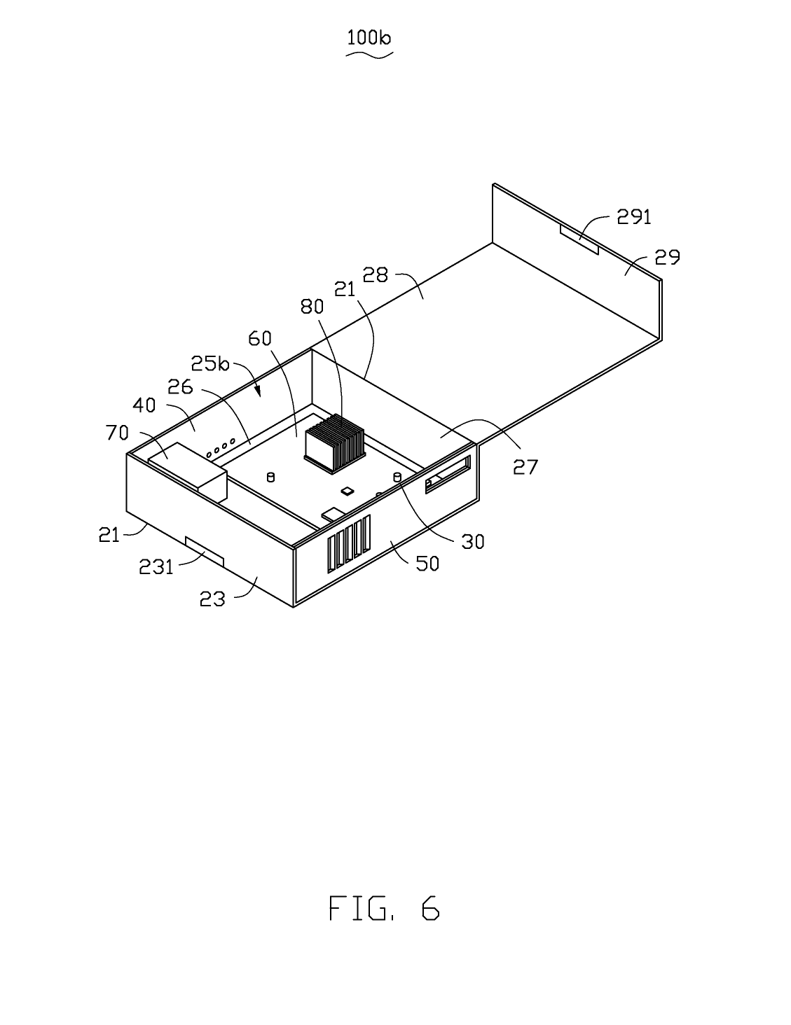

FIG. 6 illustrates assembly of the electronic device 100b, wherein the chassis 10b is opened. A U-shaped configuration is defined by the first side panel 23, the bottom panel 26, and the second side panel 27 by folding the foldable panel along the plurality of folding-lines 21. The front panel 30 is received in the first opening 247b, and the rear panel 40 is received in the second opening 248b. An second inlet 25b is defined corporately by the first side panel 23, the second side panel 27, the front panel 30, and the rear panel 40. The plurality of folding-lines 21 is substantially perpendicular to the front panel 30 and the rear panel 40. The circuit board 60 is inserted through the second inlet 25b and secured on the bottom panel 26. The power supply 70 is attached to the rear panel 40 and electronically coupled to the ground line of the circuit board 60. The bezel 50 is attached to the front panel 30.

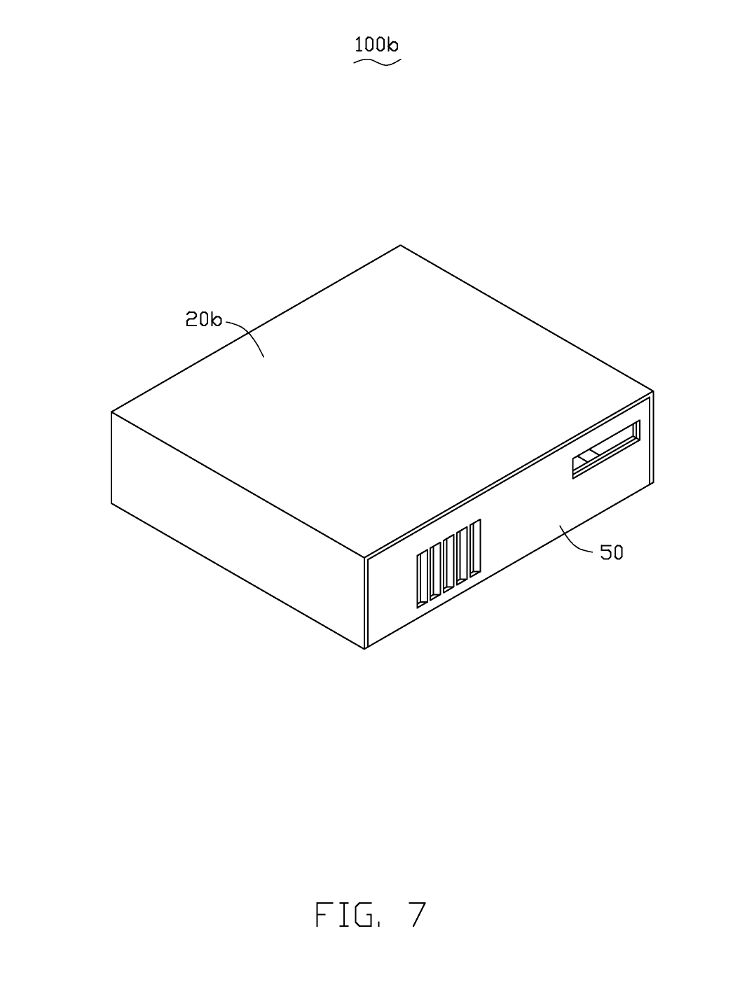

FIG. 7 illustrates the electronic device 100b in assembly, wherein the chassis 10b is closed. The covering panel 28 is folded along one folding-line 21 between the second side panel 27 and the covering panel 28 until the second inlet 25b is closed by the covering panel 28. The third side panel 29 is folded along one folding-line 21 between the covering panel 28 and the third side panel 29 until the third side panel 29 abuts the first side panel 23. The first side panel 23 can include an engaging portion 231, and the third side panel 29 can include a latching portion 291 engaging with the engaging portion 231. The engaging portion 231 and the latching portion 291 are located at opposite sides of the foldable panel. In at least one embodiment, the latching portion 291 can be a magnetic stripe, and the engaging portion 231 can be another magnetic or metallic stripe. A metallic layer is placed on inner sidewalls of the main body 20b to prevent electromagnetic interference generated by the circuit board 60 emanating from the main body 20b.

The embodiments shown and described above are only examples. Many details are often found in the art such as the other features of an electronic device. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. An electronic device comprising:
a non-metallic main body defining a first opening, and a second opening opposite to the first opening;
a front panel received in the first opening of the main body;
a metallic rear panel received in the second opening of the main body; and
a circuit board received in the main body, a ground wire of the circuit board electronically coupled to the rear panel.

2. The electronic device of claim 1, wherein the main body is made of paper or plastic materials.

3. The electronic device of claim 2, wherein the main body comprises a U-shaped base and a U-shaped cover coupled to the base, and the front panel and the rear panel are located at opposite sides of the base.

4. The electronic device of claim 3, wherein the U-shaped base is folded by a foldable plate, and the U-shaped cover is folded by another foldable plate.

5. The electronic device of claim 2, wherein the main body is substantially an enclosed configuration folded by a foldable panel.

6. The electronic device of claim 5, wherein a plurality of parallel folding-lines configured to be folded along is impressed on the foldable panel.

7. The electronic device of claim 6, wherein an extending direction of the plurality of folding-lines is substantially perpendicular to the front panel and the rear panel.

8. The electronic device of claim 5, wherein a metallic layer is placed on inner sidewalls of the main body to prevent electromagnetic interference generated by the circuit board emanating from the main body.

9. The electronic device of claim 1, further comprising a non-metallic bezel attached to the front panel.

10. An electronic device comprising:
an enclosed main body comprising a foldable panel foldable along a plurality of folding-lines, the foldable panel comprising a bottom panel, and defining a first opening, and a second opening communicating with the first opening;
a front panel received in the first opening;
a metallic rear panel received in the second opening; and
a circuit board secured to the bottom panel, a ground wire of the circuit board electronically coupled to the rear panel.

11. The electronic device of claim 10, wherein the foldable panel is made of paper or plastic materials.

12. The electronic device of claim 11, wherein the main body further comprises a first side panel and a second side panel, the first side panel and the second side panel are located at opposite sides of the bottom panel; the first opening and the second opening are defined corporately by the first side panel, the bottom panel, and the second side panel.

13. The electronic device of claim 12, wherein an inlet for the circuit board inserting through is defined by the front panel, the rear panel, the first side panel, and the second side panel.

14. The electronic device of claim 13, wherein the main body further comprises a covering panel configured to cover the inlet.

15. The electronic device of claim 14, wherein the main body further comprises a third side panel mounted on the first side panel.

16. The electronic device of claim 15, wherein the first side panel comprises an engaging portion, the third side panel comprises a latching portion engaging with the engaging portion, and the engaging portion and the third side panel are located at opposite sides of the foldable panel.

17. The electronic device of claim 16, wherein the latching portion is a magnetic stripe, and the engaging portion is another magnetic or a metallic stripe.

18. The electronic device of claim 15, wherein the first side panel, the bottom panel, the second side panel, the covering panel, and the third side panel are formed by folding along the folding-lines.

19. The electronic device of claim 10, wherein a metallic layer covers on inner sidewalls of the main body to prevent electromagnetic interference generated by the circuit board emanating from the main body.
